(19) United States
(12) Patent Application Publication
(10) Pub. No.: US 2025/0351268 A1
(43) Pub. Date: Nov. 13, 2025

(54) Component Carrier, Method and Apparatus for Manufacturing the Component Carrier

(71) Applicant: AT&S (Chongqing) Company Limited, Chongqing (CN)

(72) Inventor: Yc DENG, Chongqing (CN)

(21) Appl. No.: 18/996,971

(22) PCT Filed: Jul. 17, 2023
(86) PCT No.: PCT/IB2023/057282

§ 371 Date: Jan. 17, 2025

(30) Foreign Application Priority Data
Jul. 18, 2022 (CN) 202210843374.4

(51) Int. Cl. H05K 1/11; H05K 3/00; H05K 3/42

(52) U.S. Cl. CPC H05K 1/115; H05K 3/0047; H05K 3/422; H05K 2201/09563; H05K 2203/0207; H05K 2203/0285; H05K 2203/0369; H05K 2203/072; H05K 2203/0779; H05K 2203/092; H05K 2203/095

(57) ABSTRACT

A component carrier including i) a stack having at least one electrically insulating layer structure and at least one electrically conductive layer structure; and ii) a via embedded in the stack, wherein the via has iia) a lower metal-filled part, and iib) an upper metal-filled part, wherein the upper metal-filled part is formed directly on the lower metal-filled part with an interface region in between, and wherein the interface region is substantially free of metal oxides, in particular copper oxides. Further, there is described a manufacture method and a manufacture apparatus with an electron attachment process.

### CROSS REFERENCE TO RELATED APPLICATIONS

This application is a national stage application, filed under 35 U.S.C. § 371, of International Patent Application No. PCT/IB2023/057282, filed on Jul. 17, 2023, claiming priority of patent application No. 202210843374.4 filed on Jul. 18, 2022, in China, the disclosures of these patent applications being incorporated by reference herein in their entirety.

### TECHNICAL FIELD

The disclosure relates to a component carrier, a method of manufacturing the component carrier, and to an apparatus for manufacturing the component carrier.

Thus, the disclosure may relate to the technical field of component carriers, such as printed circuit boards and IC substrates, and their manufacture.

### Technological Background

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. At the same time, component carriers shall be mechanically robust and electrically and magnetically reliable so as to be operable even under harsh conditions.

In particular, manufacturing a component carrier with a via (vertical interconnection access) along a thickness direction of the component carrier layer stack may be a challenge. Such a via may be manufactured by two or more metal-filled parts that are arranged one above the other.

FIG. 2A shows an example of conventional vias 200 embedded in electrically insulating material of a component carrier. Each via comprises a first copper-filled part 221 and a second copper-filled part 222, arranged on top of the first copper-filled part 221. The interface between both parts 221, 222 is indicated by reference sign 225. For the via on the right side, sodium peroxosulphate has been applied as an etchant to remove metal oxides. However, due to strong galvanic corrosion, the resulting interface 225 is curved like a hemisphere.

FIG. 2B shows a microscopic image of said interface 225, which can be recognized as a thin black line (demarcation line). The black color results from copper oxides 226 formed during the manufacture process (in particular by skip acidic etching). It can be further seen that some of these copper oxides 226 are comparably quite large in size and that the copper oxides 226 form a film layer.

FIG. 4A, FIG. 4B, FIG. 4C, and FIG. 4D illustrate a conventional example of a manufacturing process that forms the vias shown in FIG. 2A and FIG. 2B.

FIG. 4A: an overview of process treatment steps (further illustrated in FIGS. 4B to 4E) is shown.

FIG. 4B: a hole has been drilled in electrically insulating material of a component carrier. A first copper-filled part 221 is formed in the hole.

FIG. 4C: The upper surface of the first copper-filled part 221 is treated by plasma (O₂), ultrasonic rinse, (alkali) etching, and dry plasma. Copper oxide 226 is formed during the processing, in particular the post alkaline etching process.

FIG. 4D: A seed layer 228 is formed on top of the first copper oxide-filled part 221 (and the copper oxide 226 film).

FIG. 8A, FIG. 8B, FIG. 8C, and FIG. 8D illustrate a conventional component carrier manufacture that is very similar to the one described for FIGS. 4A to 4D. Additionally, it is shown a final step of forming the second copper-filled part 222 on top of the seed layer 228.

Conventionally, the copper oxides 226 can be removed by aggressive reducing agents, such as sodium peroxosulphate. In the present example, this step has been skipped on purpose, because these aggressive reducing (copper-etching) agents can harm the copper filled part and eventually also the embedding insulating material.

However, the copper oxides 226 at the interface 225, which have not been efficiently removed, may significantly lower the stability and integrity of the via, and further may decrease signal transmission quality.

### SUMMARY

There may be a need to manufacture a via with a high integrity in a component carrier in an efficient and robust manner. A component carrier, a manufacture method, and a manufacture apparatus are provided.

According to a first embodiment of the disclosure, there is described a component carrier, comprising: i) a (layer) stack comprising at least one electrically insulating layer structure and/or at least one electrically conductive layer structure; and ii) a via at least partially embedded in the stack (encapsulated by stack material), wherein the via comprises: iia) a lower metal-filled part (in particular copper-filled), and iib) an upper metal-filled part, wherein the upper metal-filled part is formed (directly) on the lower metal-filled part with an interface region (e.g. a demarcation line) in between, and wherein the interface region is (substantially) free of metal oxides, in particular copper oxides.

According to a further embodiment of the disclosure, there is described a method of manufacturing a component carrier (e.g. as described above), the method comprising: i) forming a stack comprising at least one electrically insulating layer structure and at least one electrically conductive layer structure; ii) forming a via hole (empty via) at least partially in the stack; iii) filling a lower part of the via hole with metal, in particular by a first plating, to provide a lower metal-filled part; iv) processing the upper surface of the lower metal-filled part by electron attachment, thereby removing metal oxide, in particular copper oxide; and v) filling an upper part of the via hole with further metal (in particular the same metal) on the electron attachment processed upper surface of the lower metal-filled part, in particular by a second plating, thereby providing an upper metal-filled part.

According to a further embodiment of the disclosure, there is described an apparatus for manufacturing a component carrier, the apparatus comprising: i) a drilling unit configured for forming a via hole at least partially in a stack that comprises at least one electrically insulating layer structure and at least one electrically conductive layer structure; ii) a plating unit configured for filling a lower part of the via hole with metal, to provide a lower metal-filled part, and filling an upper part of the via hole with further metal on the upper metal surface of the lower metal-filled part, to provide an upper metal-filled part; and iii) an electron attachment unit configured for processing the upper surface of the lower metal-filled part by electron attachment.

### Overview of Embodiments

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers. The electrically insulating layer structures may comprise organic material (in comparison to wafer technology materials, that apply inorganic material such as silicon dioxide).

In an embodiment, the component carrier comprises a (layer) stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In the context of the present document, the term “via” may in particular refer to a vertical interconnection access being an electrical connection (at least partially) in a component carrier layer stack. The via may go through the plane of one or more adjacent layers. The term “via” may include through-hole vias, buried vias, and blind vias. While vias may be used to connect only a few layers (in a stack) with each other, other vias may be used to connect all layers of a stack. In an example, the via is formed by at least two parts, including a lower part and an upper part. While a via may comprise a constant width along the vertical (z) direction, the via may comprise different widths. In an example, the via comprises a uniform shape (e.g. a circular/rectangular pillar). In another example, the via may comprise different shapes, e.g. a pillar and a (truncated) cone or a trapeze. Further, a via may include at least one electrically conductive pad section being configured as a broadening or widening. In a specific example, the interface region is located above such a pad section (which would then be the lower metal-filled part). A via may further comprise an undercut (like a constriction), for example between a pad-like (lower) structure and an (upper) pillar structure.

In the context of the present document, the term “interface region” may refer to a location, where the lower metal-filled part (in particular the upper surface of said part) and the upper metal-filled part (in particular the lower surface of the upper metal-filled part) of a via are in (direct) physical contact with each other. The interface region may be continuous between the two parts. In another example, the interface region may be discontinuous between the two parts. While in one example, the interface region may be horizontal and essentially parallel with the layers to the stack (planar interface), the interface region may be curved in another example or may have an irregular shape extending along a planar develop of said interface region, preferable deviating from this planar extension within a range of 1 to 3 μm; said planar develop may be parallel or inclined with respect to the stack. The interface region may comprise a low amount of metal oxides or may be (essentially) free of metal oxides. In an example, the via bottom may be planar/flat during an etching process, whereby the via center flow rate may be higher than a via edge area flow rate. For this reason, the via center area may be etched more compared to edge area.

In the context of the present document, the term “essentially free” may refer to the circumstance that a method step (in particular electron attachment) is applied that reliably removes at least half of the amount of the present metal oxide. It may be desired to remove completely the metal oxide. Nevertheless, it may be technically only possible to remove the majority of metal oxides or nearly all metal oxides, while some unremovable residues may remain. Thus, the term “essentially free” may refer to a clear intention and method step to remove all metal oxide, even though some metal oxide may inevitably remain. For example, with “essentially free of metal oxides” may be meant a maximum amount of said metal (copper) oxide of 1% (in weight, for example by EDX analysis) or less, in particular 0.75% or less, more in particular 0.5% or less. In other words, concentration (in weight) of the metal (copper) can be 99% or more, in particular 99.5% or more. In comparison to conventional methods (see FIG. 2b), the amount of metal (copper) oxide may be reduced by 50% or more, in particular 75% or more, in particular 80% or more, in particular 90% or more, more in particular 95% or more, more in particular 99% or more. In a specific example, the concentration of the element oxygen can be reduced by electron attachment from around 5% to around 0.2% (in weight, e.g. based on EDX analysis).

In the context of the present document, the term “electron attachment treatment” may in particular refer to a treatment method that includes the application of an electron emission apparatus. The emitted electrons may collide with molecules of a gas, thereby producing reactive agents. In other words, the electrons may attach to molecules of the gas, thereby forming negatively charged ions. These reactive agents/ions (in particular reducing agents) may then chemically react with a component carrier (surface) under manufacture. In an example, the reducing agent may be applied to remove metal oxides (in a reduction reaction) from the interface region within a component carrier preform. In a specific example, negatively charged hydrogen ions are produced in a hydrogen/nitrogen gas, wherein the ions may efficiently reduce metal oxides of a metal-filled via part.

According to an exemplary embodiment, the disclosure may be based on the idea that a via in a component carrier may be manufactured in an efficient and robust manner with high integrity, when an interface region between a lower metal-filled part and an upper metal-filled part of the via (the upper metal-filled part thereby being directly arranged on the upper surface of the lower metal-filled part) is kept (essentially) free of metal oxides, in particular copper oxides. By taking this measure, stability and signal transmission quality of the via may be significantly improved.

According to a preferred embodiment, the presence of metal oxide at the via interface region is reduced/prevented by an electron attachment treatment process that may be provided to the upper surface of the lower metal-filled part before the upper metal-filled part is formed. Electron attachment may be a dry, non-destructive treatment method that has been shown to be surprisingly efficient in removing the undesired metal oxide during the manufacture process without harming the via material.

Conventionally, surface treatment (of the upper surface of the lower metal-filled part) is done by etching, for example using aggressive copper-etching chemicals such a sodium peroxosulphate. However, these substances may be harmful to the metal surface and thereby reduce stability and/or signal transmission quality of the respective via.

The described approach may, however, increase the (metal) interface region bonding force (thereby improving stability and via integrity), deoxidize even small via hole (e.g. diameter<20 μm) (thereby improving miniaturization), and may reduce costs and waste (in particular of acid to be recycled), thereby also being environmentally friendly.

According to an embodiment, the interface region is configured as a continuous region of space between the lower metal-filled part and the upper metal-filled part. In an example, the interface region is configured as a (essentially) horizontal and/or planar layer structure that is oriented in a comparable manner (in particular parallel) to the orientation of the layers of the stack (i.e. the x-y plane). In an example, the interface region is located (essentially) at the same vertical height. In another example, the interface region is located at different vertical heights. In an example, the interface topography reflects a manufacture step of the alkaline etching (product-by-process feature).

According to a further embodiment, the via is at least partially embedded in at least one electrically insulating layer structure of the stack (for example one or more (enforced) resin and/or solder resist layer structures).

According to a further embodiment, the via comprises at least one undercut along the stack thickness direction (z). In this context, the term “undercut” may in particular refer to a constriction and/or a recess of the via along the vertical direction (along z). While in one example, the undercut is present around the whole via width, the undercut may only be present at a part of the via in another example.

According to a further embodiment, the undercut is located at the lower metal-filled part and/or at the upper metal-filled part. In an example, the undercut is located at a comparable vertical height with respect to the interface region.

According to a further embodiment, a diameter of the undercut varies along the stack thickness direction (z). In an example, the undercut is located at a contact region between the via and the at least one electrically insulating layer structure.

According to a further embodiment, the undercut reflects a manufacture step of treating, in particular etching, the portion of the via formed in the stack where the upper metal-filled part will be formed, particularly up to the upper metal surface of the lower metal-filled part. According to a further embodiment, the undercut is provided in between the two extremities of said lower metal-filled part or said upper metal-filled part.

According to a further embodiment, the undercut comprises a variable diameter in the length of said lower metal-filled part or said upper metal-filled part from a lower diameter to a higher diameter on one extremity of said one of said lower metal-filled part or said upper metal-filled part.

In an example, said interface region is curved towards the extremity of the said lower metal-filled part or said upper metal-filled part, where the undercut is not provided. In other words, said interface region is curved away from the extremity of the said lower metal-filled part or said upper metal-filled part, where the undercut is located.

According to a further embodiment, the undercut is arranged at a comparable height in the stack thickness direction (z) as the interface region. In a further example, the undercut is located essentially at the same vertical level of the via as the interface region.

According to a further embodiment, the component carrier is configured as an integrated circuit, IC, substrate. In the context of this document, the term “IC substrate” may refer to an established technical term that refers to a small high-density PCB (i.e. comprising comparable materials, in particular organic material). An IC substrate may also be termed a chip-size PCB (or high-density PCB), wherein the term “chip-size” may refer to the circumstance that the IC substrate comprises along the x-y plane a size that is comparable to the size of an electronic component (in particular an IC chip) that is placed in the z direction on the IC substrate. Hereby, the IC substrate size may be exactly the same, slightly smaller, or slightly larger than said electronic component. In an example, size difference (extension in the x-y plane) between IC and IC substrate size may be 75% or lower, in particular 50% or lower, more in particular 25% or lower.

Thereby, efficient and robust vias may be provided for an IC substrate to enable a reliable electrical contact with an electronic component (IC chip).

According to a further embodiment, the at least one electrically insulating layer structure comprises a solder resist layer structure. This may provide the advantage that a robust via may be manufactured (at least partially) in an outermost region of the stack. This may further enable a reliable electric connection of the component carrier to a further entity (e.g. an electronic component or another component carrier.

While in one example, the via may be (at least partially) embedded in (enforced) resin material (or other typical component carrier materials), the via may be (at least partially) embedded in a solder resist layer structure. The solder resist protects the electrically conductive structures from forming undesired electric connections (short-circuits) with solder material (in a further step). The solder resist may be the outermost (or one of the outermost layers) of the stack/component carrier. In an example, the solder resist may be further covered by a surface finish. Nevertheless, there are generally no further resin layer structures laminated on top of the solder resist.

According to a further embodiment, the lower metal-filled part and/or the upper metal-filled part is configured as a tapering via. In case of the lower metal-filled part, the tapering may be away from the interface region, in other words, the diameter of the via may increase from the interface region toward the direction away from this region. In case of the upper metal-filled part, the tapering may be towards the interface region, namely the via diameter may decrease toward the interface region.

According to a further embodiment, the lower metal-filled part and/or the upper metal-filled part is configured as a circular or rectangular pillar.

According to a further embodiment, the component carrier further comprises an electrically conductive material (in particular solder material) on top of the upper metal-filled part.

According to a further embodiment, the lower metal-filled part is configured as an electrically conductive pad that is broader (in x-y direction) than the upper metal-filled part. In a specific example (see FIG. 1), the lower metal-filled part is configured as the electrically conductive pad and the upper metal-filled part is configured as a pillar. The width of the pad may hereby be larger than the width of the pillar.

According to a further embodiment, the width of the lower metal-filled part is (at least partially) larger than the width of the upper metal-filled part (or vice versa).

According to a further embodiment, the vias comprises (in particular at the interface region) a diameter of 100 μm or less, in particular 50 μm or less, more in particular 30 μm or less, in particular 20 μm or less, more in particular 15 μm or less. This may provide the advantage that the electron attachment may even reliably treat very small regions. This may not be enabled by etching alone.

According to a further embodiment, the method further comprises: etching the upper metal surface of the lower metal-filled part, in particular using an alkaline etchant, more in particular whereby the etching forms the metal oxide (copper oxide). The etching step may be necessary to provide a high-quality upper metal surface. Etching may be performed in particular to i) remove organic contaminated metal (copper) (contamination may result from UV laser drilling), ii) remove adhesion promoter treated surface. As an alkali (line) etchant for example an ammonia-based etchant may be applied. Nevertheless, the post etching process such as drying, rinsing, and storing may lead to the formation of the undesired metal oxides.

According to a further embodiment, the method further comprises: electroless plating the lower metal-filled part subsequently to the electron attachment process. Electroless plating may be applied as an established technique to provide a seed layer on a high quality, metal oxide-reduced or -depleted interface region. According to a further embodiment, the method further comprises (subsequently) using electroplating to form the upper metal-filled part. Plating on top of the seed layer may be especially efficient. An advantage of an electroless plating (in particular within a close time window after the electron attachment process) may prevent that the metal gets oxidized again due to exposure to air.

According to a further embodiment, the method is at least partially performed by a wafer technology-based apparatus (the manufacture apparatus being configured as a wafer technology-based apparatus). Electron attachment treatment may be applied in the technical field of wafer processing. Thus, an established technology may be transferred in a straightforward manner to printed circuit board manufacture processes. Since there is no formation of vias in wafer processing, it has so far not been considered to transfer electron attachment treatment to printed circuit board manufacture. Wafer manufacture and printed circuit board manufacture may be generally completely separated process environments. Wafers are normally circular, while component carrier preforms are generally rectangular (panels). Insulating materials in wafer manufacture are inorganic (e.g. silicon oxide), while insulating materials of component carriers are normally organic (e.g. resin).

According to a further embodiment, the electron attachment process is based on negatively charged hydrogen ions as a reducing agent. In particular, the emitted electrons may collide with hydrogen (H₂) molecules (e.g. in an inert gas (e.g. nitrogen or argon) atmosphere), thereby forming negatively charged hydrogen ions (H⁻). The later are not stable and will rapidly react as a reducing agent with the metal oxides of the interface region, thereby removing these. In this manner, a surprisingly efficient but non-destructive (and dry) cleaning method for the interface region may be provided.

According to a further embodiment, the method is free of a micro-etching step and/or of a soft etching step (acidic etching step). In other words, the method is free of a non-alkaline (and/or copper etching) etching step. In particular, the method is free of an etching step that applies one of peroxosulphate, in particular sodium peroxosulphate (Na₂S₂O₈), iron chloride, etc. Sodium peroxosulphate is an acidic soft etchant solution, so that acidic (i.e. non-alkaline) soft etchant solutions may not be used in the described method. Alkali soft etching (e.g. ammonia base solution) may nevertheless be applied. This may provide the advantage that an undesired (but so far necessary) step can be avoided that may harm the upper surface of the lower metal-filled part (see e.g. the right via of FIG. 2B). The non-alkaline etchant may generally be a copper-etching substance that removes a portion of the upper metal surface of the lower metal-filled part. This step may harm or even destroy part of a mandatory metal structure. Further, if such an aggressive etchant can be avoided, the method may be environmentally more friendly. Further, costs for buying etchant and for recycling may be saved.

According to a further embodiment, an alkaline etching step is applied to replace a non-alkaline (in particular peroxosulphate) etching step. In combination with electron attachment treatment for removing metal oxide, the via (and interface region) quality may be significantly improved.

According to a further embodiment, the method further comprises at least one of the following processing steps: plasma treatment (in particular based on oxygen), dry plasma treatment (e.g. using an inert gas such as argon or nitrogen), ultrasonic rinsing. This may provide the advantage that established and reliable treatment methods may be applied additionally to the interface region in a straightforward manner.

In an embodiment, the stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electrooptical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimidetriazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supraconductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1A illustrates a component carrier according to an exemplary embodiment of the disclosure.

FIG. 1B shows a microscopic image of the interface region according to an exemplary embodiment of the disclosure.

FIG. 2A shows a conventional component carrier.

FIG. 2B shows a conventional demarcation line with a plurality of metal oxides.

FIG. 3A, FIG. 3B, FIG. 3C, FIG. 3D, and FIG. 3E illustrate a component carrier manufacture according to an exemplary embodiment of the disclosure.

FIG. 4A, FIG. 4B, FIG. 4C, and FIG. 4D illustrate a conventional component carrier manufacture.

FIG. 5 illustrates an electron attachment unit according to an exemplary embodiment of the disclosure.

FIG. 6 illustrates a manufacture apparatus according to an exemplary embodiment of the disclosure.

FIG. 7A, FIG. 7B, FIG. 7C, FIG. 7D, and FIG. 7E illustrate a component carrier manufacture according to an exemplary embodiment of the disclosure.

FIG. 8A, FIG. 8B, FIG. 8C, and FIG. 8D illustrate a conventional component carrier manufacture.

### DETAILED DESCRIPTION OF EXEMPLARY EMBODIMENTS

The illustrations in the drawings are schematically presented. In different drawings, similar or identical elements are provided with the same reference signs.

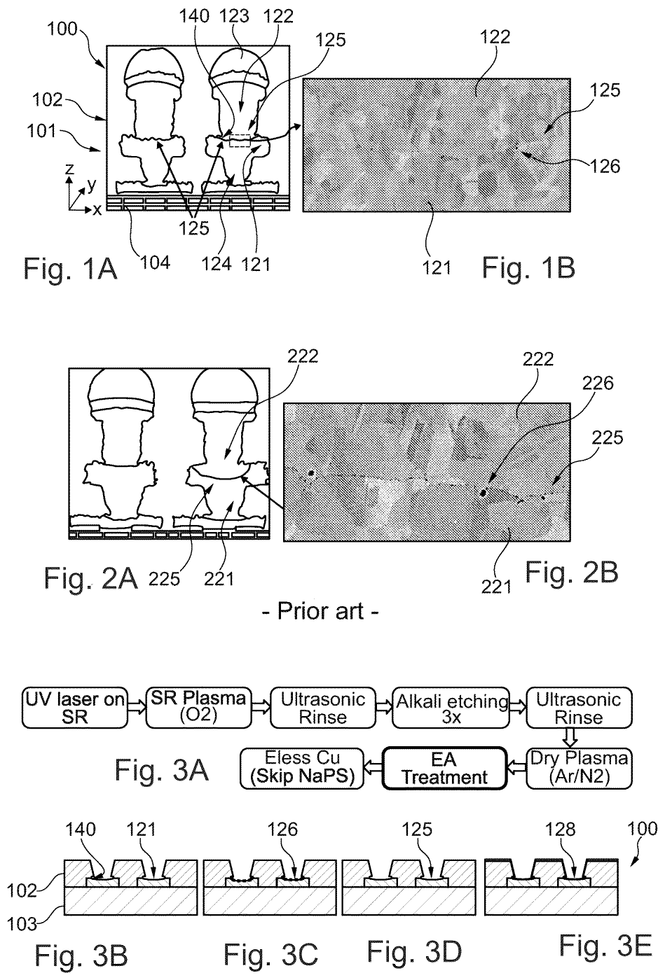

FIG. 1A illustrates a component carrier 100 according to an exemplary embodiment of the disclosure. The component carrier 100 comprises a stack 101 comprising at least one electrically insulating layer structure 102 and at least one electrically conductive layer structure 104. In this example, the at least one electrically insulating layer structure 102, in which the vias 120 are embedded, comprises at least partially a solder resist layer structure.

According to the shown embodiment, two vias 120 are embedded in the electrically insulating layer structure 102 of the stack 101, wherein each via 120 comprises a lower metal-filled part 121 and an upper metal-filled part 122. According to alternative embodiments only one via or multiple vias can be provided; for the sake of simplicity the FIGS. 1A, 3B, 3C, 3D and 3E are shown as the embodiment where two vias are provided. The upper metal-filled part 122 (pillar-shape) is formed directly on top of the lower metal-filled part 121 (pad-like and tapering shape) with an interface region 125 in between. Said interface region 125, being shown in FIG. 1B in detail, reflects a manufacturing step of forming (e.g. by electroplating) the upper metal-filled part 122 on top of the upper surface (in z direction) of the lower metal-filled part 121. The interface region 125 is configured as a continuous region of space between the lower metal-filled part 121 and the upper metal-filled part 122.

The vias 120 comprise a respective undercut 140 in the stack thickness direction (z), wherein the undercut 140 is located close to the interface region 125 between the lower metal-filled part 121 and the upper metal-filled part 122 at a comparable height in the stack thickness direction as the interface region 125. The diameter of the undercut 140 varies hereby along the stack thickness direction. The undercut 140 reflects a manufacture step of etching (see FIG. 3B). The undercut 140 can comprise a variable diameter along the length of the lower metal-filled part 121 and the upper metal-filled part 122 from a lower diameter to a higher diameter or vice versa. The interface region 125 can be curved towards the extremity of the lower metal-filled part 121 or the upper metal-filled part 122 (where the undercut 140 is arranged). In this example, the undercut 140 is located between the pad-like lower part 121 and the pillar-like upper part 122.

FIG. 1B shows a microscopic detailed image of the interface region 125 according to an exemplary embodiment of the disclosure. The interface region 125 can be seen as a continuous region (demarcation line) between plated copper material of the upper/lower part 121/122. In comparison to a conventional interface 225 (see FIG. 2B), the interface region 125 is substantially free of metal (copper) oxides 126 (see black dots at the interface region). The formulation “substantially” has been chosen on purpose, because there can still be metal oxides visible. However, the amount of metal oxides 126 significantly lower than of conventional interfaces, thereby improving stability, integrity, and signal transmission quality. In numbers, the amount of metal oxides at the interface region 125 can be reduced by 75%, in particular 90% or more. Specifically, the concentration of copper is 99.5% (in weight) or more, while the concentration of copper oxide is below 0.5%.

FIG. 3A, FIG. 3B, FIG. 3C, FIG. 3D, and FIG. 3E illustrate a component carrier manufacture according to an exemplary embodiment of the disclosure.

FIG. 3A: gives an overview of the treatment steps of the upper surface of the lower metal-filled part 121: i) UV laser treatment on solder resist), ii) plasma (here oxygen) cleaning, iii) ultrasonic rinsing, iv) alkali etching, v) further ultrasonic rinsing, vi) further plasma (here argon or nitrogen) cleaning, vii) electron attachment treatment, and viii) metal plating (here electroless to form a seed layer to plate afterwards the upper metal filled part 122).

FIG. 3B: an insulating solder resist layer structure 102 is formed on a further electrically insulating layer structure 103 of the stack 101. A hole has been drilled in the solder resist layer structure 102 and the lower part of the hole has been filled with copper to provide the lower metal-filled part 121. The alkaline etching is applied to treat the upper surface of the lower metal-filled part 121, whereby also a part of the solder resist layer structure 102 is removed, resulting in the undercut 140 directly above the vertical height of the upper surface.

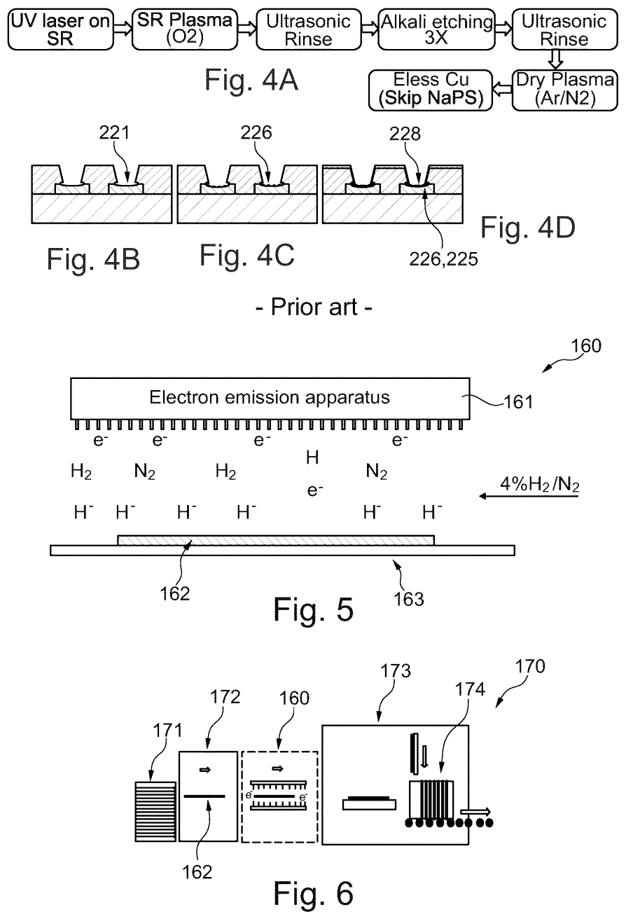

FIG. 3C: it is illustrated that at this stage of the manufacture process, the upper surface of the lower metal-filled part 121 is covered by metal (copper) oxides 126 (in particular formed during the etching process). Conventionally (compare FIG. 4A and FIG. 4B), the upper metal-filled part 122 would now be formed directly on the upper surface of the lower metal-filled part 121, resulting in a low-quality interface region 125 that comprises the high amount of metal oxide 126.

FIG. 3D: to overcome the drawback of the prior art, the upper surface is processed with the electron attachment treatment. Thereby, the metal oxides 126 are removed in a surprisingly efficient manner without doing any harm to the lower metal-filled part 121.

FIG. 3E: a seed layer 128 (electroless plated metal layer structure) is formed on the electron attachment treated upper surface of the lower metal-filled part 121, thereby providing a high-quality interface region 125 with low amount of metal oxides 126. Afterwards (not shown), the upper metal-filled part is formed by filling the rest of the hole by electroplating.

In the above described manner, surface treatment with aggressive chemicals, such as sodium peroxosulphate, can be avoided.

FIG. 5 illustrates an electron attachment unit 160 according to an exemplary embodiment of the disclosure. The unit 160 comprises an electron emission apparatus 161 that is configured to provide electrons with respect to a component carrier under manufacture (component carrier preform 162). The component carrier preform 162 (e.g. a panel) is transported on a transport line 163 below the electron emission apparatus 161. Between the component carrier preform 162 and the electron emission apparatus 161, there is provided a gas atmosphere of hydrogen and nitrogen. In this example, an ambient pressure chamber with 4% H₂ in N₂ is applied. Low-energy electrons (<10 eV) are emitted from the electron emission apparatus 161 and collide with the H₂ gas molecules, some are captured by H₂ molecules and produce negative ions (H) and neutral atoms (H):

Dissociative attachment: H₂+e⁻->H₂⁻>H⁻+H

Direct attachment: H+e⁻->H⁻

The formed H⁻ moves to the CuO film surface of the component carrier preform 162, driven by an electrical field, and promotes surface the following deoxidation reaction: 2 H⁻+CuO->Cu+H₂O.

The electrons that originate from the electron emission apparatus 161 thus collide with the hydrogen and from thereby negatively charged hydrogen ions (H⁻). The electron attachment process is based in this example on using these negatively charged hydrogen ions as a reducing agent for the component carrier preform 162. In particular, the reducing agent reduces the metal oxides, thereby removing these.

FIG. 6 illustrates a manufacture apparatus 170 according to an exemplary embodiment of the disclosure. The apparatus 170 comprises in the first place a panel processing unit 171 configured to form a component carrier preform 162 with a layer stack. Further, the apparatus 170 comprises a drilling unit 172 configured for forming via holes in a stack 101. The steps described in FIGS. 3B and 3C are then applied (for example in a further unit that is not shown).

The apparatus 170 further comprises the electron attachment unit 160 (see FIG. 5 above) for processing the upper surface of the lower metal-filled part 121 by electron attachment treatment (see FIG. 3D).

Furthermore, the apparatus 170 comprises a plating unit 173 for filling an upper part 122 of the via hole 120 with further metal on the upper metal surface of the lower metal-filled part 121 to provide an upper metal-filled part 122. The plating unit 173 can be further configured to fill a lower part 121 of the via hole with metal to provide the lower metal-filled part 121 before the electron attachment treatment. During plating, the component carrier preforms 162 can be stored in a panel storing device 174.

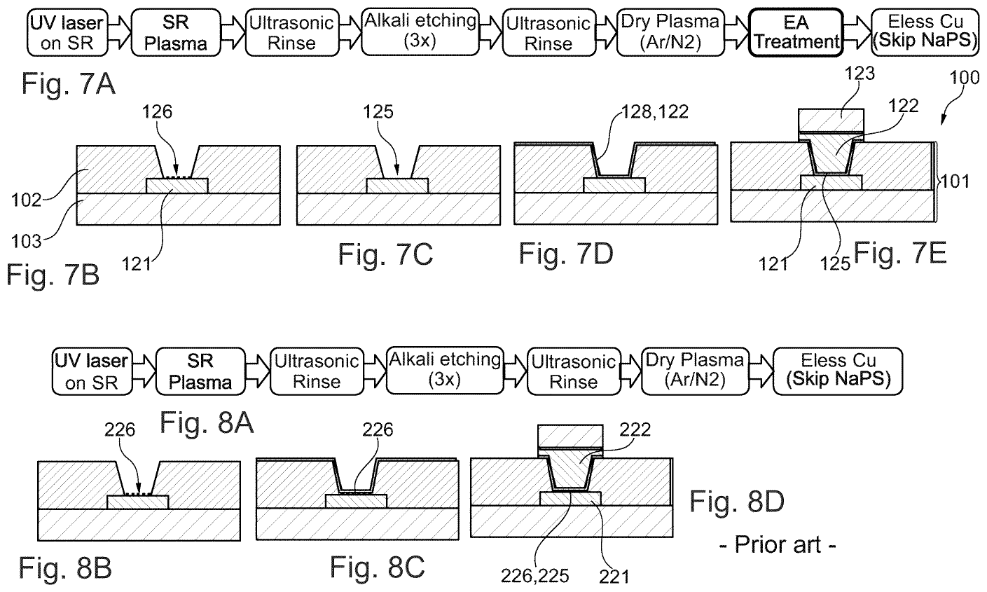

FIG. 7A, FIG. 7B, FIG. 7C, FIG. 7D, and FIG. 7E illustrate a component carrier manufacture according to an exemplary embodiment of the disclosure. The process is very similar to the one described for FIG. 3 above in detail. Additionally, it is shown that the upper metal-filled part 122 is formed by plating metal on the seed layer 128 (see FIG. 7D). In this example, the final via 120 extends over the solder resist layer structure 102. Further, an electrically conductive connection material (e.g. a solder ball) 123 is provided on top of the via 120 to thereby provide a large external electronic contact for the stack 101. The interface region 125 is of high quality, because the electron attachment treatment has been applied in FIG. 7c, thereby removing the metal oxides 126 (see FIG. 7B).

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

Reference signs

| | |
|---|---|
| 100 | Component carrier |
| 101 | Stack |
| 102 | Electrically insulating layer structure, solder resist |
| 103 | Further electrically insulating layer structure |
| 104 | Electrically conductive layer structure |
| 120 | Via |
| 121 | Lower metal-filled part |
| 122 | Upper metal-filled part |
| 123 | Electrical connection material, solder ball |
| 125 | Interface region |
| 126 | Metal (copper) oxide |
| 128 | Electroless plated metal layer structure, seed layer |
| 140 | Undercut |
| 160 | Electron attachment unit |
| 161 | Electron emission apparatus |
| 162 | Component carrier preform, panel |
| 163 | Transport line |
| 170 | Apparatus |
| 171 | Component carrier preform processing unit |
| 172 | Drilling unit |
| 173 | Plating unit |
| 174 | Component carrier preform storing device |
| 220 | Prior art via |
| 221 | Prior art lower part |
| 222 | Prior art upper part |
| 225 | Prior art interface |
| 226 | Prior art copper oxide |

1. A component carrier, comprising:
a stack comprising at least one electrically insulating layer structure and at least one electrically conductive layer structure; and
a via at least partially embedded in the stack, wherein the via comprises:
a lower metal-filled part, and
an upper metal-filled part,
wherein the upper metal-filled part is formed directly on the lower metal-filled part with an interface region in between, and
wherein the interface region is substantially free of metal oxides.

2. The component carrier according to claim 1,
wherein the interface region is configured as a continuous region of space between the lower metal-filled part and the upper metal-filled part.

3. The component carrier according to claim 1,
wherein the via is at least partially embedded in the at least one electrically insulating layer structure of the stack, and
wherein the via comprises at least one undercut along the stack thickness direction.

4. The component carrier according to claim 3,
wherein the undercut is located at the lower metal-filled part and/or at the upper metal-filled part.

5. The component carrier according to claim 3,
wherein a diameter of the undercut varies along the stack thickness direction.

6. The component carrier according to claim 3,
wherein the undercut is arranged at a comparable height in the stack thickness direction as the interface region.

7. The component carrier according to claim 1, being configured as an integrated circuit, substrate.

8. The component carrier according to claim 1, wherein the at least one electrically insulating layer structure comprises a solder resist layer structure.

9. A method of manufacturing a component carrier, the method comprising:
forming a stack comprising at least one electrically insulating layer structure and at least one electrically conductive layer structure;
forming a via hole at least partially in the stack;
filling a lower part of the via hole with metal to provide a lower metal-filled part;
processing the upper surface of the lower metal-filled part by electron attachment, thereby removing metal oxide; and
filling an upper part of the via hole with further metal on the electron attachment processed upper surface of the lower metal-filled part, thereby providing an upper metal-filled part.

10. The method according to claim 9, further comprising:
etching the upper metal surface of the lower metal-filled part.

11. The method according to claim 10,
wherein etching comprises using an alkaline etchant.

12. The method according to claim 10,
whereby the etching forms the metal oxide.

13. The method according to claim 9, further comprising:
electroless plating the lower metal-filled part subsequently to the electron attachment process to form the upper metal-filled part.

14. The method according to claim 9,
wherein the method is at least partially performed by a wafer technology-based apparatus.

15. The method according to claim 9,
wherein the electron attachment process is based on negative hydrogen ions as a reducing agent.

16. The method according to claim 9,
wherein the method is free of a sodium peroxosulphate, Na₂S₂O₈, etching step.

17. The method according to claim 9, further comprising at least one of the following processing steps:
plasma treatment based on oxygen, dry plasma treatment based on argon and/or nitrogen, ultrasonic rinsing.

18. An apparatus for manufacturing a component carrier, the apparatus comprising:
a drilling unit configured for forming a via hole in a stack that comprises at least one electrically insulating layer structure and at least one electrically conductive layer structure;
a plating unit configured for filling a lower part of the via hole with metal, to provide a lower metal-filled part-, and filling an upper part of the via hole with further metal on the upper metal surface of the lower metal-filled part, to provide an upper metal-filled part; and
an electron attachment unit configured for processing the upper surface of the lower metal-filled part by electron attachment.

19. The apparatus according to claim 18, being configured as a wafer technology-based apparatus.
